(19) United States
(12) Patent Application Publication
(10) Pub. No.: US 2009/0101961 A1
(43) Pub. Date: Apr. 23, 2009

(54) MEMORY DEVICES WITH SPLIT GATE AND BLOCKING LAYER

(76) Inventors: Yue-Song He, San Jose, CA (US); Len Mei, San Jose, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/876,557

(22) Filed: Oct. 22, 2007

(51) Int. Cl. H01L 29/788; H01L 21/336

(52) U.S. Cl. 257/319; 438/267; 257/E21.422; 257/E29.3

(57) ABSTRACT

The present disclosure provides a memory device having a cell stack and a select gate formed adjacent to the cell stack. The cell stack includes a tunneling dielectric layer, a charge storage layer, a blocking dielectric layer, a tantalum-nitride layer, and a control gate layer. When a positive bias is applied to the control gate and the select gate, negative charges are injected from a channel region of a substrate through the tunneling dielectric layer and into the charge storage layer to thereby store the negative charges in the charge storage layer. When a negative bias is applied to the control gate, negative charges are tunneled from the charge storage layer to the channel region of the substrate through the tunneling dielectric layer.

### TECHNICAL FIELD

The present invention relates to memory devices and, in particular, to non-volatile memory devices with a split gate and a blocking layer.

### BACKGROUND

Some conventional embedded flash memory devices utilize split gate floating gate devices with source side junction Fowler-Nordheim (FN) tunnel erase to provide page erase functionality. These memory cells have limited scalability. In one example, a conventional 0.18 um embedded flash memory cell cannot be scaled due to the source erase option. The source junction needs to be graded enough to improve the post cycling induced read current degradation. Since the graded source junction uses a large portion of the channel region area, to prevent punch-through of the device, the cell cannot be scaled accordingly. Thus, the cell size is not small enough to be competitive in many products, such as flash memory products, which limits application.

To overcome the deficiencies of floating gate devices, a SONOS (Silicon-Oxide-Nitride-Oxide-Silicon) type of cell has been suggested. However, although the SONOS type cell can provide smaller cell size and low operation voltage compared with a float-gate source side erase cell, the data retention is worse than the floating gate device due to thin tunneling oxide used in the device.

### SUMMARY

The present disclosure overcomes the deficiencies of conventional memory devices by providing a scalable memory device having a smaller cell size of at least less than 180 nm. In one embodiment, the scalable memory cell of the present disclosure may be sized to approximately 90 nm. The present disclosure describes a split-gate silicon-rich-nitride based non-volatile memory device, such as a SG-TANOROS (Split-Gate TAntalum-Nitride-high K Oxide-nitride Rich-Oxide-Silicon) memory cell for embedded flash memory applications.

In various implementations, the SG-TANOROS cell provides low operating voltages, fast read and writes times, and smaller cell size. The present disclosure provides for a program operation for fast write speed, such as, for example, source side hot carrier injection (i.e., hot electron injection), which allows for fast write speed. The present disclosure provides for an erase operation, such as, for example, channel FN tunneling, which allows for smaller cell size and lower operation voltage.

Embodiments of the present disclosure provide a non-volatile memory device having a cell stack and a select gate formed adjacent to a sidewall of the cell stack. The cell stack includes a tunneling dielectric layer formed on a channel region of a substrate, a charge storage layer formed on the tunneling dielectric layer, a blocking dielectric layer formed on the charge storage layer, a tantalum-nitride layer formed on the blocking dielectric layer, and a control metal gate layer formed on the tantalum-nitride layer. In one aspect, when a positive bias is applied to the control gate, the select gate and the source of the device, negative charges are injected from the channel region of the substrate through the tunneling dielectric layer and into the charge storage layer to thereby store the negative charges in the charge storage layer. In another aspect, when a negative bias is applied to the control gate, negative charges are FN tunneled from the charge storage layer to the channel region of the substrate through the tunneling dielectric layer. In one example, applying a negative bias to the control gate stores positive charges in the charge storage layer.

Embodiments of the present disclosure provide a method for manufacturing a non-volatile memory device. The method includes forming a tunneling dielectric layer on a channel region of a substrate, forming a charge storage layer on the tunneling dielectric layer, forming a blocking dielectric layer on the charge storage layer, forming a tantalum-nitride layer on the blocking dielectric layer, forming a control gate layer on the tantalum-nitride layer and forming a select gate adjacent to the charge storage layer. In one aspect, applying a positive bias to the control gate and the select gate stores negative charges in the charge storage layer, and applying a negative bias to the control gate stores positive charges in the charge storage layer.

The scope of the disclosure is defined by the claims, which are incorporated into this section by reference. A more complete understanding of embodiments will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIGS. 1A-1L show a process for forming a non-volatile memory device in accordance with one embodiment of the present disclosure.

FIG. 2 shows one embodiment of a program operation for the non-volatile memory device formed from the process of FIGS. 1A-1L.

FIG. 3 shows one embodiment of an erase operation for the non-volatile memory device formed from the process of FIGS. 1A-1L.

Embodiments and their advantages are best understood by referring to the detailed description that follows. It should be appreciated that like reference numerals are used to identify like elements illustrated in one or more of the figures.

### DETAILED DESCRIPTION

The present disclosure describes a split-gate silicon-rich-nitride with high dielectric constant material as a blocking layer based non-volatile memory device, such as a SG-TANOROS memory cell for embedded flash memory applications. In one aspect, the SG-TANOROS memory cell may be referred to as a Split Gate TANOROS memory cell. In various implementations, the SG-TANOROS cell provides improved data retention, improved reliability, deep erase capability, fast read and writes times, and smaller cell size.

The memory cell of the present disclosure allows for lower deep erase capability due to high dielectric blocking layer and the utilization of metal gate. With a channel erase approach, a smaller memory cell size is achievable. The memory cell of the present disclosure is compatible with existing CMOS (complementary metal oxide semiconductor) processes thereby allowing for lower wafer costs and lower test costs.

Embodiments of the present disclosure provide for a program operation for fast write speed, such as, for example, source side hot carrier injection (i.e., hot electron injection), which allows for fast write speed. Embodiments of the present disclosure provide for an erase operation, such as, for example, channel FN tunneling, which allows for smaller cell size and lower operation voltage. Embodiments of the present disclosure provide a scalable memory cell of at least less than 180 nm. For example, in one embodiment, the scalable memory cell may be sized to approximately 90 nm. These and other aspects of the present disclosure will be discussed in greater detail herein.

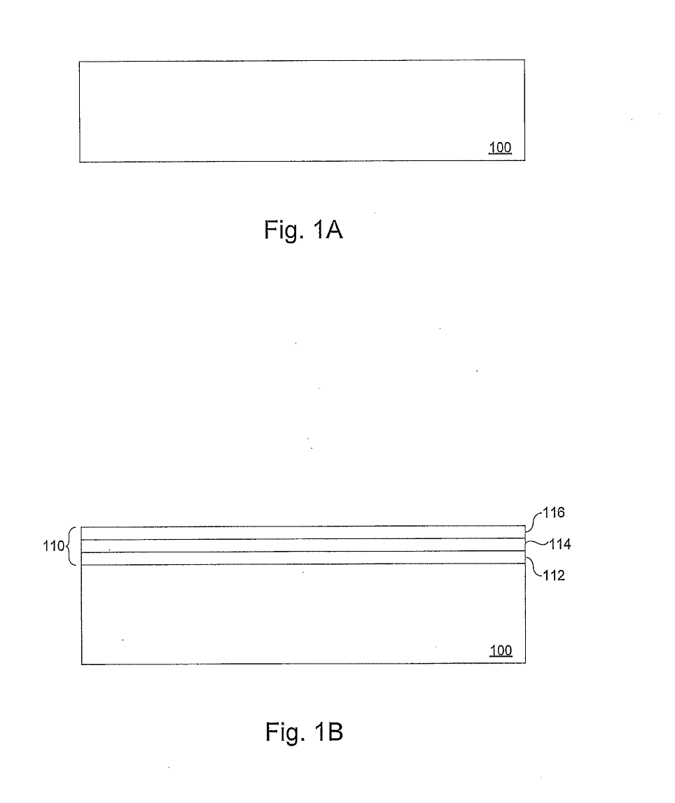

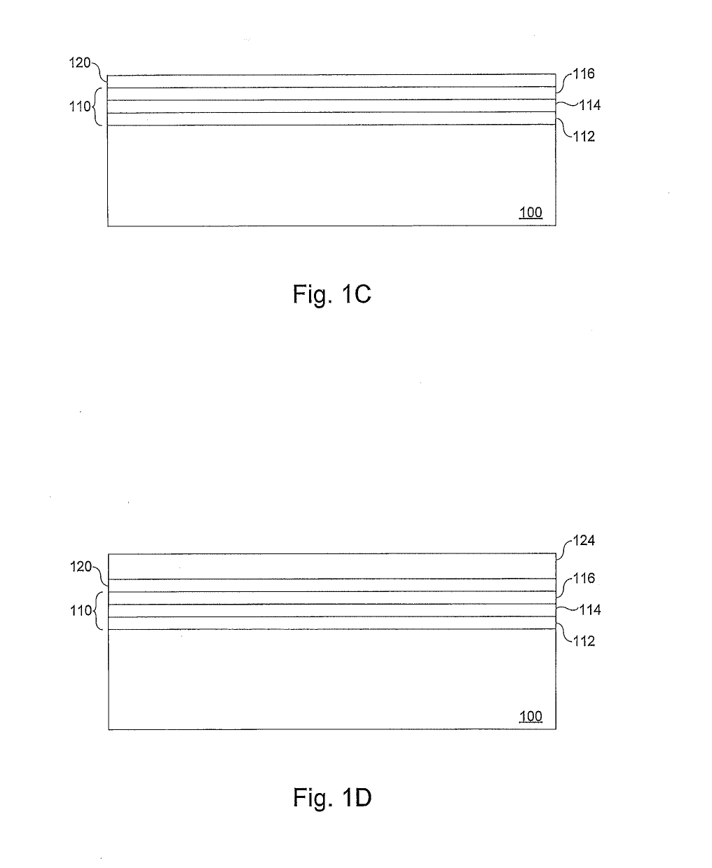

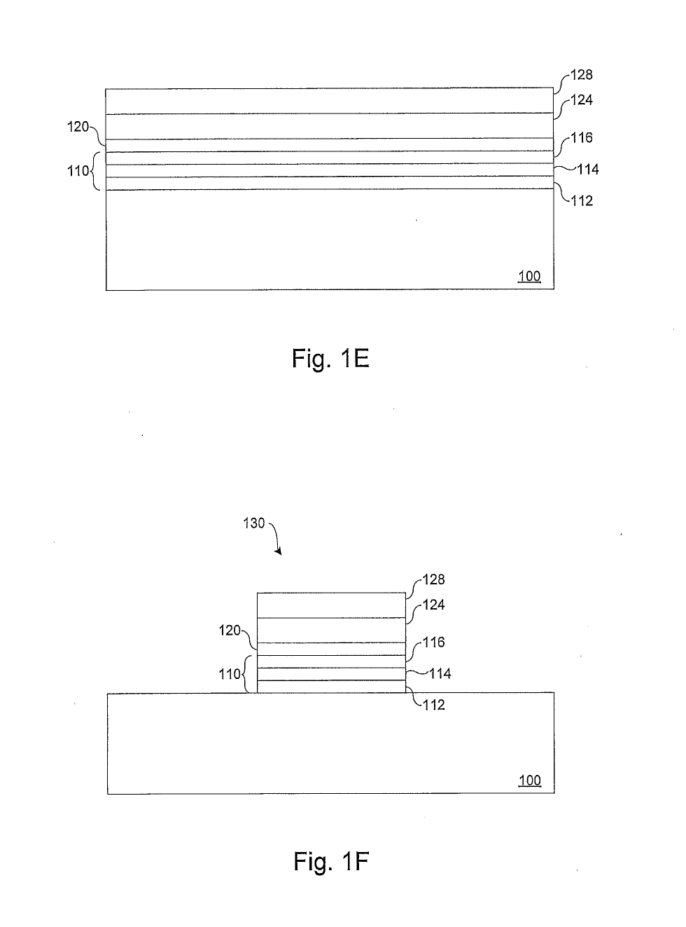

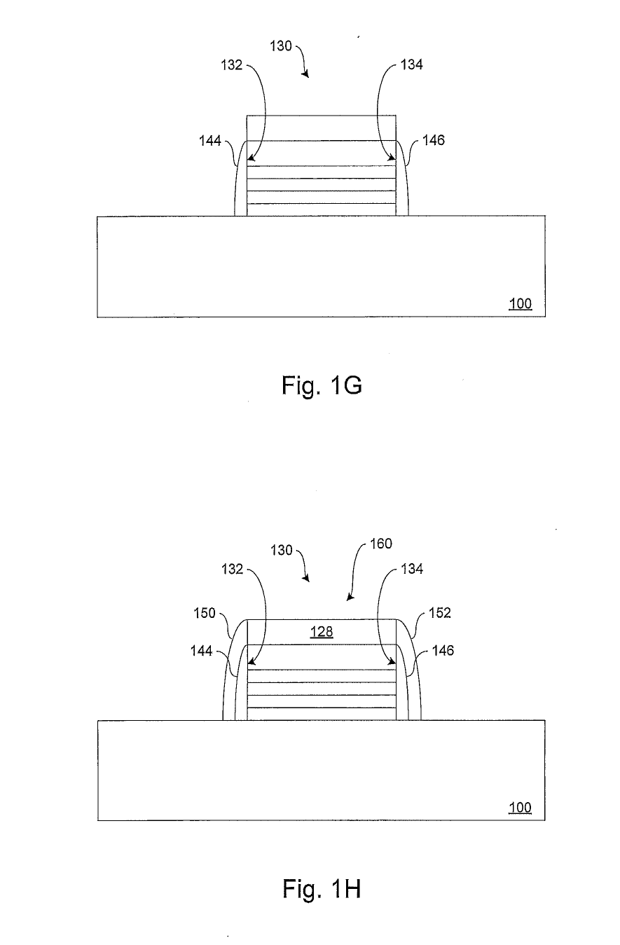

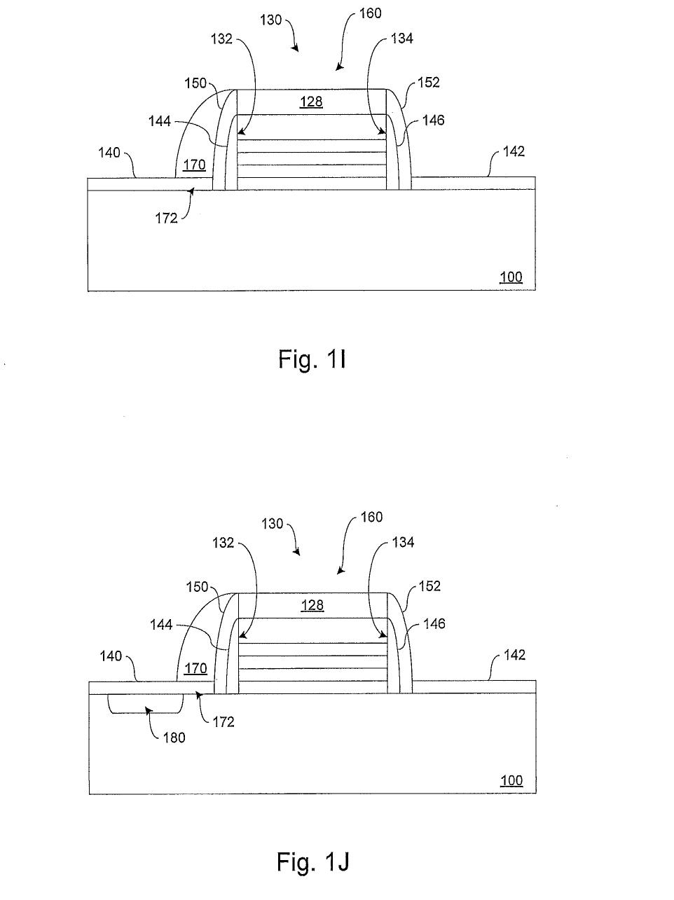

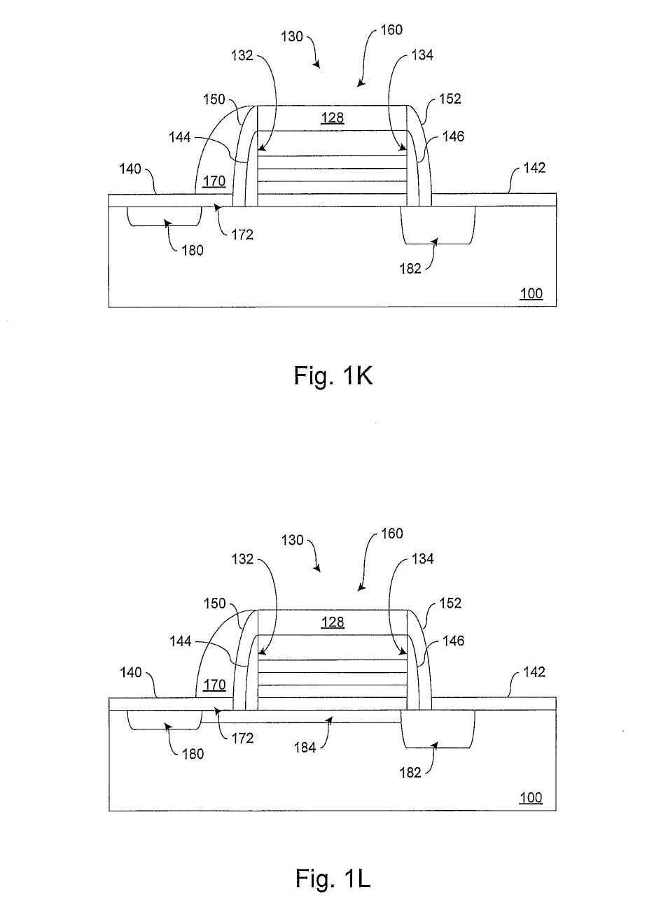

FIGS. 1A-1L show one embodiment of a process for forming a memory cell of the present disclosure. In one embodiment, the memory cell comprises a non-volatile SG-TANOROS memory cell for flash memory applications having a high dielectric constant (high K) material and tantalum-nitride layer as a blocking layer and a silicon rich nitride region that functions as a charge storage region.

FIG. 1A shows one embodiment of a substrate 100 comprising a semiconductor material. In one implementation, substrate 100 comprises a P-type mono-crystalline silicon (Si) substrate.

FIG. 1B shows one embodiment of forming an ONAO (oxide-nitride-Al₂O₃ oxide) layer 110 on substrate 100. In one implementation, ONAO layer 110 includes a first oxide layer 112, a nitride layer 114 and a second oxide layer 116.

In one embodiment, first oxide layer 112 is formed on substrate 100 and comprises a tunneling dielectric region of silicon-dioxide (SiO₂). In one aspect, first oxide layer 112 may be formed by a thermal process or a high temperature deposition process. In one implementation, first oxide layer 112 may be formed with a thickness of approximately 25-55 A (Angstrom). In another implementation, first oxide layer 112 may be formed with a thickness of approximately 40 A.

In one embodiment, nitride layer 114 is formed on first oxide layer 112 and comprises a charge storage region of a silicon rich nitride material, such as, for example, silicon-rich-nitride (SiₓN_{y}). In one implementation, nitride layer 114 may be form with a thickness of approximately 50-80 A. In another implementation, nitride layer 114 may be form with a thickness of approximately 65 A.

In one embodiment, second oxide layer 116 is formed on nitride layer 114 and comprises a blocking dielectric region of aluminum-oxide (Al₂O₃). In one implementation, second oxide layer 116 may be formed with a thickness of approximately 85-115 A. In another implementation, second oxide layer 116 may be formed with a thickness of approximately 100 A.

FIG. 1C shows one embodiment of forming a first gate layer 120 on second oxide layer 116 of ONO layer 110. In one embodiment, first gate layer 120 comprises a layer of tantalum-nitride (TaN). In another embodiment, first gate layer 120 comprises a layer titanium-nitride (TiN). In one implementation, first gate layer 120 may be formed with a thickness of approximately 155-185 A. In another implementation, first gate layer 120 may be formed with a thickness of approximately 150 A.

FIG. 1D shows one embodiment of forming a second gate layer 124 on first gate layer 120. In various implementations, second gate layer 124 may be referred to as an electrode layer comprising tungsten (W) or tungsten-nitride (WN).

In one embodiment, tunneling dielectric region (i.e., first oxide layer 112) is formed between charge storage region (i.e., nitride layer 114) and substrate 100 as a tunnel dielectric and also to reduce charge leakage from the charge storage region (i.e., 114) to substrate 100. Blocking dielectric region (i.e., second oxide layer 116) is formed between charge storage region (i.e., 114) and first gate layer 120 to reduce charge leakage from the charge storage region (i.e., 114) to first gate layer 120. In one implementation, first and second gate layers 120, 124 form a control gate.

FIG. 1E shows one embodiment of forming a protection layer 128 on electrode layer 124. In one implementation, protection layer 128 comprises a region of silicon-nitride (SiN). It should be appreciated that protection layer 128 may be referred to as a hard mask without departing from the scope of the present disclosure.

FIG. 1F shows one embodiment of etching a portion of layers 110, 112, 114, 116, 120, 124, 124 to form a cell stack 130 on substrate 100. It should be appreciated that various types of generally known etching techniques may be used without departing from the scope of the present disclosure.

FIG. 1G shows one embodiment of forming oxide sidewall portions 144, 146 on substrate 100 and sidewalls 132, 134 of cell stack 130. As shown in FIG. 1G, cell stack 130 comprises first and second sidewalls 132, 134 that extend vertically from substrate 100. As further shown in FIG. 1G, first and second sidewall portions 144, 146 are formed on first and second sidewalls 132, 134 of cell stack 130, respectively, so as to extend vertically adjacent thereto. In one implementation, each sidewall portion 144, 146 comprises a layer of oxide (e.g., silicon dioxide: SiO₂) that insulates and/or isolates end portions of layers 112, 114, 116, 120, 124 from other layers including substrate 100 to reduce charge leakage.

FIG. 1H shows one embodiment of forming spacers 150, 152 on substrate 100 and on sidewall portions 144, 146. As shown in FIG. 1H, first and second spacers 150, 152 are formed adjacent to first and second sidewalls 132, 134 of cell stack 130, respectively, with sidewall portions 144, 146 interposed therebetween. Spacers 150, 152 comprise silicon-nitride (SiN), which is similar to protection layer 128. As further shown in FIG. 1H, an upper portion of each spacer 150, 152 contacts end portions of protection layer 128, respectively, to form a cap 160 over cell stack 130. In one implementation, cap 160 comprises a series combination of SiN components including first spacer 150, protection layer 128 and second spacer 152.

FIG. 11 shows one embodiment of forming oxide layers 140, 142 on substrate 100 and adjacent to sidewall portions 144, 146, respectively. As further shown in FIG. 11, a select gate 170 is formed on oxide layer 140 and adjacent to first spacer 150. In one implementation, oxide layers 140, 142 comprise silicon dioxide (SiO₂) and select gate 170 comprises poly-silicon (poly-Si). As further shown in FIG. 11, select gate 170 may be formed adjacent to first sidewall 132 of cell stack 130 with first spacer 150 and first sidewall portion 144 interposed therebetween. In various implementations, select gate 170 may be referred to as a word line.

As shown in FIG. 11, a layer 140 is interposed between select gate 170 and substrate 100. Hence, in one embodiment, a portion of oxide layer 140 under select gate transistor poly gate (i.e., layer 170) may be referred to as a select gate oxide 172. In one implementation, select gate oxide 172 may be formed with a thickness of approximately 80-200 A. In another implementation, select gate oxide 172 may be formed with a thickness of approximately 100-150 A. In still another implementation, select gate oxide 172 may be formed with a thickness of approximately 120 A.

FIG. 1J shows one embodiment of forming a drain region 180 in substrate 100. In one implementation, drain region 180 is formed by implanting (n+) dopant in the area of drain region 180 of substrate 100. In one implementation, drain region 180 is formed in substrate 100 below oxide layer 140 and adjacent to select gate 170.

FIG. 1K shows one embodiment of forming a source region 182 in substrate 100. In one implementation, source region 182 is formed by implanting (n+) dopant in the area of source region 182 of substrate 100. In one implementation, source region 182 is formed in substrate 100 below oxide layer 142.

FIG. 1L shows one embodiment of forming a channel region 184 in substrate 100. In one implementation, channel region 184 comprises a P-type channel region that is formed adjacent first oxide layer 112 of cell stack 130 and interposed between drain region 180 and source region 182. In other words, as shown in FIG. 1L, P-type channel region 184 is formed in substrate 100 between N-type source and drain regions 180, 182, and charge storage region (i.e., nitride layer 114) overlies channel region 184.

It should be appreciated that, in one embodiment, channel region 184 may comprise a P-type well formed in substrate 100 and may be isolated from other portions of substrate 100 by PN junctions and/or dielectric regions, and tunnel dielectric region (i.e., first oxide layer 112) is formed on channel region 184 in manner so as to overlap or overlie at least a portion of drain and source regions 180, 182. It should be appreciated that, in various embodiments, channel region 184 may be formed at any time during the process as discussed in reference to FIGS. 1A-1L.

The fabrication process discussed in reference to FIGS. 1A-1L should not limit the present disclosure. In various implementations, any one or more of layers 112, 114, 116, 120, 124, 128, 140, 142, 150, 152, 170 may be patterned using a separate mask, and the P and N conductivity types may be reversed. The present disclosure should not be limited to any particular cell geometry. In various implementations, all or part of channel region 184 may be vertical, and all or part of charge storage region (i.e., nitride layer 114) may be formed in a trench in substrate 100. The memory cell stack 130 may comprise a multi-level cell with the charge storage region (i.e., nitride layer 114) divided into sub-regions each of which may store one bit of information. The present disclosure should not be limited to particular materials except as defined by the claims.

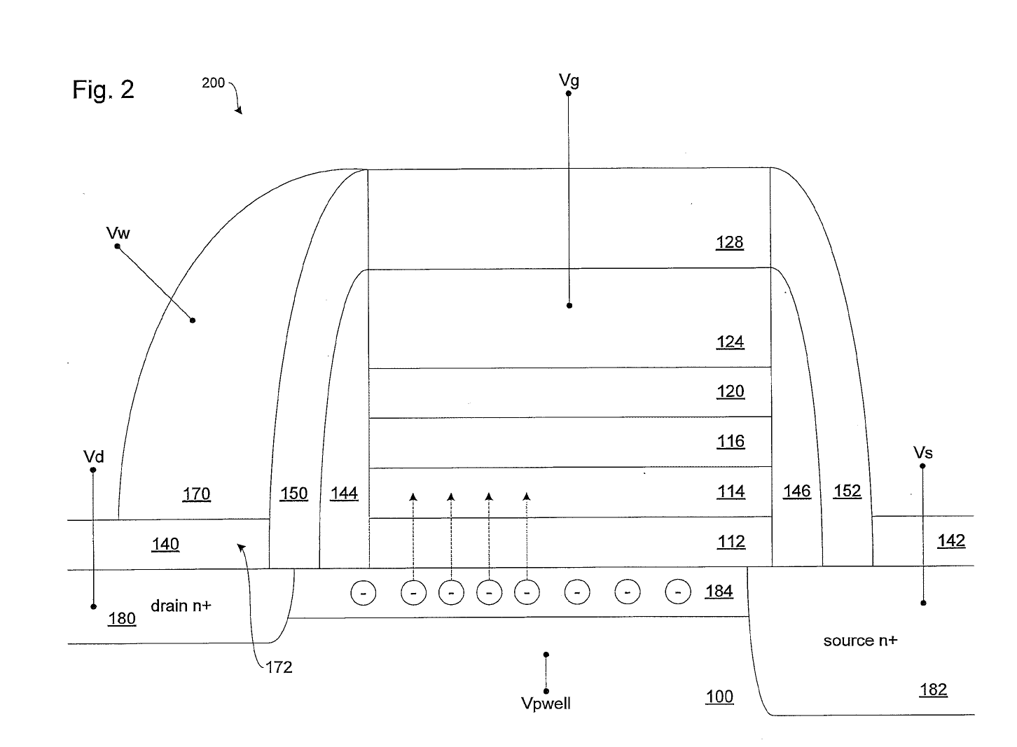

FIG. 2 shows one embodiment of a program operation for memory cell 200 formed from the process of FIGS. 1A-1L. In one aspect, the program operation shown in FIG. 2 may be referred to as channel hot electron injection of electrons from channel region 184 to nitride layer 114. As described herein, a positive bias is applied to gate region 124 and source region 182 to inject electrons into nitride layer 114 at the gap between select gate 170 and gate region 124. In one embodiment, the nitride layer 114 functions as a charge storage layer for storing or trapping negative charges.

In one implementation, when voltages are applied to gate region 124 (e.g., Vg of approx. +5 to 12V and, in one instance, approx. +10.5V), source region (e.g., Vs of approx. +4.5 to 7.5V and, in one instance, approx. +6V), and drain region 182 (e.g., Vd of approx. 0V) relative to channel region 184, some electrons in channel region 184 gain enough energy to tunnel through dielectric region (i.e., first oxide layer 114) into charge storage region (i.e., nitride layer 114). The electrons become trapped in the charge storage region thereby increasing the threshold voltage of the memory cell 200, which may be referred to as a program state or “0” state.

In one embodiment, the threshold voltage (Vt) may be sensed by sensing the current between source and drain regions 180, 182 when suitable voltages are applied to gate region 124, substrate 100, and source/drain regions 180, 182. In another embodiment, when a negative voltage is applied to gate region 124 relative to channel region 184 or source/drain regions 180, 182, the threshold voltage (Vt) of the memory cell 200 drops, which may be referred to as an erase state or “1” state.

The following table describes one embodiment of the approximate node voltages for programming memory cell 200 of FIG. 2:

Program Voltage Table

| | Range | | Approx. | |
|---|---|---|---|---|
| Vg | +5 to +12 | V | +10.5 | V |
| Vd | ~0 | V | 0 | V |
| Vs | +4.5 to +7.5 | V | +6.0 | V |
| Vw | +0.8 to +2 | V | +1.2 | V |
| Vpwell | ~0 | V | 0 | V |

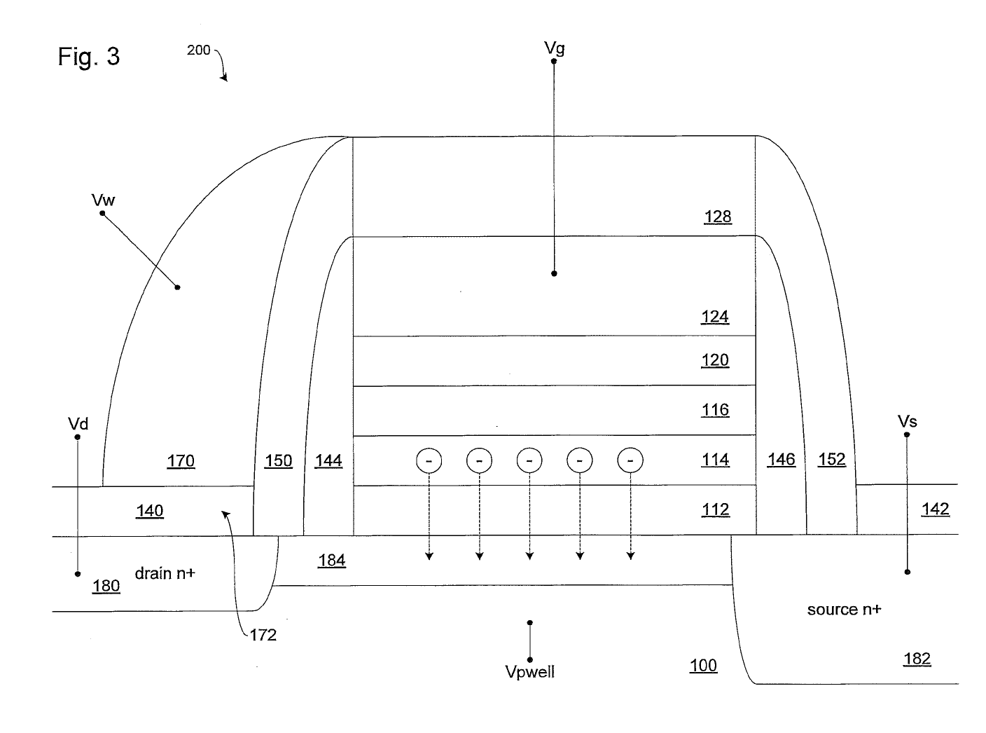

FIG. 3 shows one embodiment of an erase operation for memory cell 200 formed from the process of FIGS. 1A-1L. In one aspect, the erase operation shown in FIG. 3 may be referred to as channel FN tunneling of holes from channel region 184 to nitride layer 114. As described herein, a negative bias is applied to gate region 124 (e.g., Vg of approx. −10.5V) and a positive bias is applied to Vpwell region of substrate 100 (e.g., Vpwell of approx. +8V) to inject holes into nitride layer 114 from channel region 184 of substrate 100. In one embodiment, the nitride layer 114 functions as a charge storage layer for storing or trapping positive charges. In one example, as shown in FIG. 3, when a negative bias is applied to gate region 124, negative charges are FN tunneled from nitride layer 114 (i.e., charge storage layer) to channel region 184 of substrate 100 through first oxide layer 112 (i.e., tunneling dielectric layer).

As such, in one embodiment, when a negative bias is applied to gate region 124 (i.e., control gate), negative charges are tunneled out by FN tunneling from nitride layer 114 through first oxide layer 112 to channel region 184 of substrate 100. In one example, the cell threshold voltage (Vt) is reduced and gets into erase state.

The following table describes one embodiment of the approximate node voltages for erasing memory cell 200 of FIG. 3:

Erase Voltage Table

| | Range | Approx. |
|---|---|---|
| Vg | −8 to −12 V | −10.5 V |
| Vd | Float | Float |
| Vs | Float | Float |
| Vw | Float | Float |
| Vpwell | +8 to +9 V | +8 V |

In one implementation, to program memory cell 200 using channel hot electron injection, a voltage difference is created between source/drain regions 180, 182, and gate region 124 is driven to a positive voltage relative to channel region 184 for inversion from type P to type N. As such, current flows between source/drain regions 180, 182 through channel region 184 to inject hot electrons from channel region 184 of substrate 100 to charge storage region (i.e., nitride layer 114), which pass through tunneling dielectric region (i.e., first oxide layer 112) to the charge storage region. As previously discussed, these hot injected electrons become trapped in the charge storage region (i.e., nitride layer 114). In another implementation, memory cell 200 may be erased by driving the gate region 124 to a negative voltage relative to channel region 128 and/or one or both of source/drain regions 180, 182.

Embodiments described herein illustrate but do not limit the disclosure. It should be understood that numerous modifications and variations are possible in accordance with the principles of the disclosure. Accordingly, the scope and spirit of the disclosure should be defined by the following claims.

1. A device for non-volatile memory, the device comprising:
a cell stack comprising:
a tunneling dielectric layer formed on a channel region of a substrate;
a charge storage layer formed on the tunneling dielectric layer;
a blocking dielectric layer formed on the charge storage layer;
a tantalum-nitride layer formed on the blocking dielectric layer; and
a control gate layer formed on the tantalum-nitride layer;
a select gate formed adjacent to a first sidewall of the cell stack,
wherein, when a selected bias of a first polarity is applied to the control gate and the select gate, charges of an opposite polarity are injected from the channel region of the substrate through the tunneling dielectric layer and into the charge storage layer to thereby store the opposite polarity charges in the charge storage layer, and
wherein, when a selected bias of a second polarity opposite to the first polarity is applied to the control gate, charges of the first polarity are tunneled from the charge storage layer to the channel region of the substrate through the tunneling dielectric layer.

2. The device of claim 1, wherein the substrate comprises a P-type mono-crystalline silicon (Si) substrate.

3. The device of claim 1, wherein the tunneling dielectric layer comprises silicon-dioxide (SiO₂) having a thickness of approximately 25-55 A.

4. The device of claim 1, wherein the tunneling dielectric layer comprises silicon-dioxide (SiO₂) having a thickness of approximately 40 A.

5. The device of claim 1, wherein the charge storage region comprises silicon-nitride (Si₃N₄) having a thickness of approximately 50-80 A.

6. The device of claim 1, wherein the charge storage region comprises silicon-nitride (Si₃N₄) having a thickness of approximately 65 A.

7. The device of claim 1, wherein the blocking dielectric layer comprises aluminum-oxide (Al₂O₃) having a thickness of approximately 85-115 A.

8. The device of claim 1, wherein the blocking dielectric layer comprises aluminum-oxide (Al_{O}₃) having a thickness of approximately 100 A.

9. The device of claim 1, wherein the tantalum-nitride layer is formed with a thickness of approximately 155-185 A.

10. The device of claim 1, wherein the tantalum-nitride layer is formed with a thickness of approximately 170 A.

11. The device of claim 1, wherein the control gate layer comprises at least one of tungsten (W) and tungsten-nitride (WN).

12. The device of claim 1, further comprising a protection layer formed on the control gate, wherein the protection layer comprises silicon-nitride (SiN).

13. The device of claim 1, wherein the tunneling dielectric layer, charge storage layer, blocking dielectric layer and control gate form a memory cell stack on the substrate.

14. The device of claim 1, further comprising first, second and third oxide regions, wherein the first oxide region is formed between the first sidewall of the cell stack and the select gate, and wherein the second oxide region is formed adjacent to a second sidewall of the cell stack, and wherein the third oxide region is formed between the select gate and the substrate.

15. The device of claim 14, further comprising first and second spacers, wherein the first spacer is formed between the first oxide region and the select gate, and wherein the second spacer is formed adjacent to the second oxide region, and wherein the first and second spacers comprise silicon-nitride (SiN).

16. The device of claim 1, wherein the select gate comprises poly-silicon (noly-Si).

17. (canceled)

18. The device of claim 1, further comprising a drain region and a source region formed in the substrate, wherein the drain region is formed adjacent to the select gate, and wherein the source region is formed adjacent to the cell stack opposite the drain region, and wherein the channel region is formed between the drain and source regions.

19. A method for manufacturing a non-volatile memory device, the method comprising:
forming a tunneling dielectric layer on a channel region of a substrate;
forming a charge storage layer on the tunneling dielectric layer;
forming a blocking dielectric layer on the charge storage layer;
forming a tantalum-nitride layer on the blocking dielectric layer;
forming a control gate layer on the tantalum-nitride layer; and
forming a select gate adjacent to the charge storage layer,
wherein applying a selected bias of a first polarity to the control gate and the select gate stores charges of an opposite polarity in the charge storage layer, and
wherein applying a selected bias of a second polarity opposite to the first polarity to the control gate stores first polarity charges in the charge storage layer.

20. The method of claim 19, wherein applying a selected bias of a first polarity to the control gate and the select gate causes charges of an opposite polarity to be injected from the channel region of the substrate through the tunneling dielectric layer and into the charge storage layer for storage of the opposite polarity charges in the charge storage layer.

21. The method of claim 19, wherein applying a selected bias of a second polarity opposite to the first polarity to the control gate causes charges of the first polarity to be tunneled from the channel region of the substrate through the tunneling dielectric layer and into the charge storage layer for storage of the first polarity charges in the charge storage layer.

22. The method of claim 19, wherein the tunneling dielectric layer comprises silicon-dioxide (SiO₂) having a thickness of approximately 40 A, wherein the charge storage region comprises silicon-nitride (Si₃N₄) having a thickness of approximately 65 A, and wherein the blocking dielectric layer comprises aluminum-oxide (Al₂O₃) having a thickness of approximately 100 A.

23. The method of claim 19, wherein the tantalum-nitride layer is formed with a thickness of approximately 170 A, and wherein the control gate layer comprises at least one of tungsten (W) and tungsten-nitride (WN).

24. The method of claim 19, wherein the select gate comprises poly-silicon (poly-Si)

25. The method of claim 19, further comprising a drain region and a source region formed in the substrate, wherein the drain region is formed adjacent to the select gate, and wherein the source region is formed adjacent to the cell stack opposite the drain region, and wherein the channel region is formed between the drain and source regions.

26. The device of claim 1, further comprising a select gate oxide formed between the select gate and the substrate.

27. The device of claim 26, wherein the select gate oxide comprises silicon-dioxide (SiO₂) having a thickness of approximately 80-200 A.

28. The device of claim 26, wherein the select gate oxide comprises silicon-dioxide (SiO₂) having a thickness of approximately 120 A.
